(19) United States
(12) Patent Application Publication
(10) Pub. No.: US 2025/0294694 A1
(43) Pub. Date: Sep. 18, 2025

(54) DISPLAY DEVICE, MANUFACTURING METHOD THEREOF, AND ELECTRONIC DEVICE INCLUDING THE SAME

(71) Applicant: Samsung Display Co., LTD., Yongin-si (KR)

(72) Inventors: Byung Chul SHIN, Yongin-si (KR); Hyun Seop SONG, Yongin-si (KR); Young Bin KIM, Yongin-si (KR)

(21) Appl. No.: 18/919,491

(22) Filed: Oct. 18, 2024

(30) Foreign Application Priority Data
Mar. 14, 2024 (KR) 10-2024-0035739

(51) Int. Cl. H05K 5/03

(52) U.S. Cl. CPC H05K 5/03

(57) ABSTRACT

A display device includes: a display panel; a panel cover disposed on a back surface of the display panel and including one or more alignment marks located on a back surface of the panel cover; a printed circuit board disposed on the back surface of the panel cover and including a ground area located around the one or more the alignment marks; and a protective member disposed on the printed circuit board and including a transparent portion at least partially overlapping the ground area in a plan view.

The application claims priority to Korean Patent Application No. 10-2024-0035739, filed on Mar. 14, 2024, and all the benefits accruing therefrom under 35 U.S.C. § 119, the content of which in its entirety is herein incorporated by reference.

### BACKGROUND

### Field

The present disclosure relates to a display device, a manufacturing method thereof, and an electronic device including the same.

### Discussion

As technology develops, a display device may include electronic components that perform various functions. The electronic component may include a main printed circuit board (“PCB”) of the display device, and may be connected to the main printed circuit board through a connector to receive power sources or transmit and receive signals.

To protect a display panel included in the display device, the display device may include a display panel cover. In this case, in a process of manufacturing the display device, the main printed circuit board may be disposed on the display panel cover. In addition, a protective member for protecting components of the main printed circuit board may be disposed on the main printed circuit board. When the main printed circuit board and the protective member are not disposed in the intended position during a manufacturing process, driving reliability of the display device may deteriorate.

The above description is only intended to help understand the background technology of the technical ideas of the present invention. Therefore, it cannot be understood as content corresponding to prior art known to those skilled in the art to which the present invention pertains.

### SUMMARY

An aspect of the present invention is to provide a display device with improved reliability of a manufacturing process by aligning a printed circuit board on a panel cover based on alignment marks, a manufacturing method thereof, and an electronic device including the same.

Another aspect of the present invention is to provide a display device with improved driving reliability by disposing a protective member on a printed circuit board based on transparent portions.

A display device according to embodiments of the present invention includes: a display panel; a panel cover disposed on a back surface of the display panel and including one or more alignment marks located on a back surface of the panel cover; a printed circuit board disposed on the back surface of the panel cover and including a ground area located around the one or more alignment marks; and a protective member disposed on the printed circuit board and including a transparent portion at least partially overlapping the ground area in a plan view.

The protective member may be disposed to cover at least a portion of the printed circuit board, and the transparent portion may include a light transmissive material.

The transparent portion may have an area equal to or larger than the ground area in a plan view.

The protective member may cover the one or more alignment marks.

The printed circuit board may be disposed to overlap a contact area disposed on the back surface of the panel cover in the plan view, and the one or more alignment marks may be disposed outside the contact area.

The one or more alignment marks may be provided in plurality, the plurality of alignment marks may be disposed on the back surface of the panel cover, the ground area may be provided in plurality, the plurality of ground areas may be disposed on the printed circuit board, the plurality of alignment marks may be disposed adjacent to each other in a first direction, one of the plurality of ground areas may be disposed adjacent to a corresponding one of the plurality of alignment marks in a second direction, and the first direction and the second direction may intersect each other.

The display panel may further include a bending area disposed at an end of the display panel and connected to the printed circuit board. As the bending area is bent in a third direction that intersects the first direction and the second direction, the printed circuit board may be positioned on the back surface of the panel cover.

The ground area may have a ground potential.

The one or more alignment marks may have a line shape.

The one or more alignment marks may be imprinted on the panel cover.

An electronic device according to embodiments of the present invention includes: a display device for displaying an image based on input image data; and a processor for providing the input image data to the display device. The display device includes: a display panel; a panel cover disposed on a back surface of the display panel and including one or more alignment marks; a printed circuit board aligned on the panel cover based on the one or more alignment marks and including one or more ground areas; and a protective member disposed on the printed circuit board and including one or more transparent portions overlapping the one or more ground areas in a plan view.

Another aspect of the present invention relates to a manufacturing method of a display device. The manufacturing method of the display device according to embodiments of the present invention includes: preparing a panel cover including one or more alignment marks; disposing the panel cover on a back surface of a display panel; aligning a printed circuit board including one or more ground areas on the panel cover based on the one or more alignment marks; and disposing a protective member including one or more transparent portions to cover at least a portion of the printed circuit board.

The disposing of the protective member may include aligning at least a portion of the one or more transparent portions to overlap the one or more ground areas in a plan view.

The manufacturing method may further include forming each of the one or more transparent portions to have an area equal to or larger than each of the one or more ground areas in a plan view.

The disposing of the protective member may include disposing the protective member to cover at least one of the one or more alignment marks.

The preparing of the panel cover may include disposing the one or more alignment marks to be arranged on a back surface of the panel cover in a first direction.

The aligning of the printed circuit board on the panel cover may include aligning the printed circuit board so that one of the one or more ground areas is disposed adjacent to a corresponding one of the one or more alignment marks in a second direction intersecting the first direction.

The aligning of the printed circuit board on the panel cover may include bending a bending area disposed at an end of the display panel and connected to the printed circuit board so that the printed circuit board may be positioned on the back surface of the panel cover.

The one or more ground areas may have a ground potential.

The one or more alignment marks may have a line shape.

### BRIEF DESCRIPTION OF THE DRAWINGS

The accompanying drawings, which are included to provide a further understanding of the inventions, and are incorporated in and constitute a part of this specification, illustrate exemplary embodiments of the inventions, and, together with the description, serve to explain principles of the inventions.

FIG. 1 is a perspective view of a display device according to an embodiment of the present invention.

FIG. 2 is an exploded perspective view of the display device of FIG. 1.

FIG. 3 is a plan view illustrating a panel cover and a printed circuit board before a bending area of FIG. 2 is bent.

FIG. 4 is a plan view illustrating the panel cover and the printed circuit board after the bending area of FIG. 2 is bent.

FIG. 5 is a plan view illustrating the panel cover, the printed circuit board, and a protective member according to an embodiment of the present invention.

FIG. 6 is a plan view illustrating an embodiment in which the protective member of FIG. 5 is disposed on the panel cover.

FIG. 7 is a plan view illustrating another embodiment in which the protective member of FIG. 5 is disposed on the panel cover.

FIG. 8 is a plan view illustrating an embodiment of alignment marks in a state in which the protective member of FIG. 5 is disposed on the panel cover.

FIG. 9 is a flowchart illustrating a manufacturing method of a display device according to an embodiment of the present invention.

FIG. 10 is a block diagram illustrating an electronic device including a display device according to embodiments of the present invention.

FIG. 11 is a perspective view illustrating an example in which the electronic device of FIG. 10 is implemented as a tablet PC (personal computer).

### DETAILED DESCRIPTION

Hereinafter, preferred embodiments of the present invention will be described in more detail with reference to the accompanying drawings. It should be noted that in the following description, only the parts necessary to understand the operation according to the present invention will be described, and descriptions of other parts will be omitted in order to not obscure the gist of the present invention. In addition, the present invention is not limited to the embodiments described herein and may be embodied in other forms. The embodiments described herein are provided merely to explain in detail enough to enable those skilled in the art to easily implement the technical idea of the present invention.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the present invention. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as “first” and “second” may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing the relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

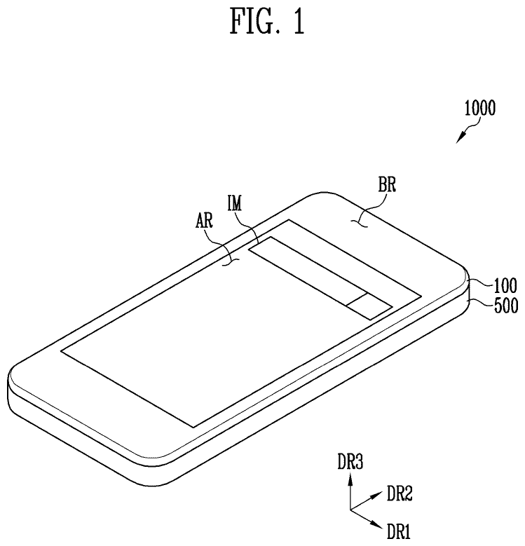

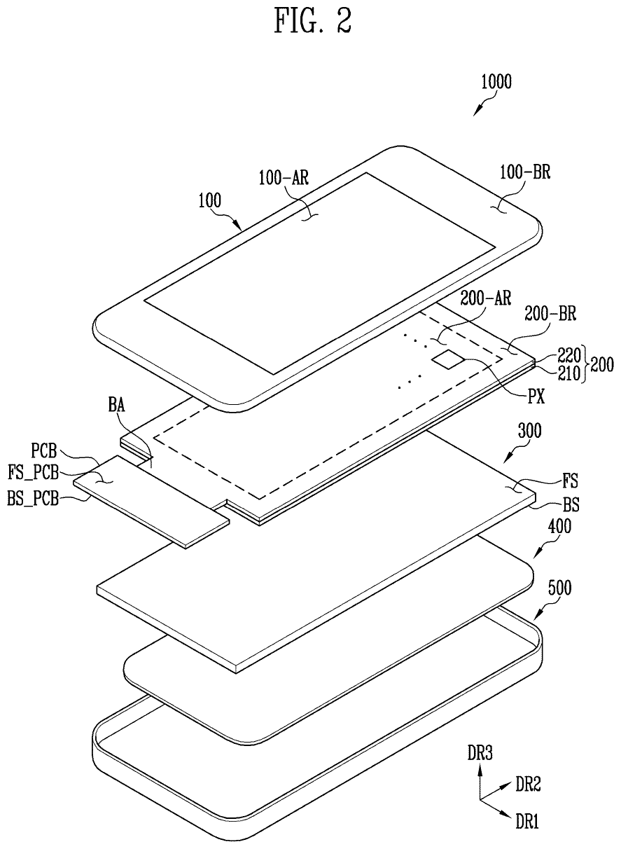

FIG. 1 is a perspective view of a display device according to an embodiment of the present invention. FIG. 2 is an exploded perspective view of the display device of FIG. 1.

Referring to FIG. 1, a display device 1000 may include a plurality of distinct areas on a display surface. For example, the display device 1000 may include a display area AR and a non-display area BR adjacent to the display area AR. The display area AR may be an area where an image IM is displayed.

The display area AR may have a rectangular shape. The non-display area BR may be positioned to surround the display area AR. However, the present invention is not limited thereto.

Referring to FIG. 2, the display device 1000 may include a window member 100, a display panel 200, a panel cover 300, a bracket 400, and a rear case 500.

The window member 100 may be disposed on an upper surface of the display panel 200. Accordingly, a display surface (for example, an upper surface in a third direction DR3) of the display panel 200 can be protected. In addition, the window member 100 may be combined with the display panel 200. For example, the window member 100 may be combined to cover the display surface of the display panel 200.

The window member 100 may include a display area 100-AR through which the image IM provided by the display panel 200 is transmitted and a non-display area 100-BR adjacent to the display area 100-AR.

The window member 100 may include an optically transparent insulating material. For example, a window WIN may include glass or plastic. In addition, the window WIN may have a multi-layer structure or a single-layer structure. For example, the window WIN may include a plurality of plastic films bonded with an adhesive, or may include a glass substrate and a plastic film bonded with an adhesive.

The display panel 200 may include a substrate 210, an encapsulation layer 220, pixels PX, a bending area BA, and a printed circuit board PCB.

The display panel 200 may have the display surface that displays the image IM and a back surface that faces the display surface. The display surface may correspond to an upper surface of the encapsulation layer 220. The back surface may correspond to a lower surface of the substrate 210.

The display panel 200 may include a display area 200-AR and a non-display area 200-BR. The display area 200-AR may be an area that displays the image IM, and may correspond to the display area 100-AR of the window member 100. The non-display area 200-BR may be adjacent to the display area 200-AR and may correspond to the non-display area 100-BR of the window member 100.

The substrate 210 may be a rigid substrate made of glass. In addition, the substrate 210 may be flexible to allow bending, folding, rolling, or the like. In this case, the substrate 210 may include an insulating material such as a polymer resin such as polyimide.

According to an embodiment, the substrate 210 may include a silicon wafer substrate formed using a semiconductor process. The substrate 210 may include a semiconductor material suitable for forming circuit elements. For example, the semiconductor material may include silicon, germanium, and/or silicon-germanium. The substrate 210 may be provided from a bulk wafer, an epitaxial layer, a silicon on insulator (“SOI”) layer, a semiconductor on insulator (“SeOI”) layer, or the like.

The encapsulation layer 220 may be disposed on the substrate 210. When the encapsulation layer 220 is in the form of an encapsulation film, the encapsulation layer 220 may include an inorganic film and/or an organic film. The encapsulation layer 220 may protect the pixels PX from moisture and oxygen. In addition, the encapsulation layer 220 may protect the pixels PX from foreign substances such as dust particles.

Among a plurality of pixels PX, pixels PX arranged along a first direction DR1 may form a pixel row, and pixels PX arranged along a second direction DR2 may form a pixel column. Each of the pixels PX may include a plurality of sub-pixels. For example, each of the plurality of pixels PX may include a first pixel configured to emit red light, a second pixel configured to emit green light, and a third pixel configured to emit blue light.

Each of the plurality of pixels PX may include a light emitting element and a pixel circuit configured to drive the light emitting element. According to one embodiment, the light emitting element may be provided in various forms. For example, the light emitting element may be an inorganic light emitting element including an inorganic material. According to one embodiment, the light emitting element may be an organic light emitting diode. However, the present invention is not limited thereto. For another example, the light emitting element may be a quantum dot light emitting diode.

The bending area BA may be a portion where the display panel 200 is folded. The bending area BA may be bent onto a back surface BS of the panel cover 300. For example, as the bending area BA is bent in a direction opposite to the third direction DR3, the printed circuit board PCB may be positioned to overlap the panel cover 300 in a plan view.

The bending area BA may include a flexible printed circuit board (“FPCB”). Accordingly, the bending area BA may electrically connect the display panel 200 and the printed circuit board PCB. For example, the display panel 200 and the printed circuit board PCB may exchange driving signals through the flexible printed circuit board. For example, the driving signals may be various signals for driving the display device 1000, such as a driving voltage, a gate signal, and a data signal. However, the present invention is not limited thereto.

The printed circuit board PCB may output signals to the display panel 200 or receive signals from the display panel 200 through the bending area BA. According to one embodiment, the printed circuit board PCB may include a connector for receiving signals from the outside. Accordingly, the printed circuit board PCB may supply at least some of the signals received from the outside to the display panel 200.

The printed circuit board PCB may be positioned on the back surface BS of the panel cover 300 as the bending area BA is bent. For example, as the bending area BA is bent, a back surface BS_PCB of the printed circuit board PCB may be in contact with the back surface BS of the panel cover 300.

The panel cover 300 may be disposed on a back surface of the display panel 200. For example, the panel cover 300 may be disposed so that a front surface FS of the panel cover 300 faces the back surface of the display panel 200. In a combined state, the panel cover 300 may be disposed between the display panel 200 and the printed circuit board PCB.

The panel cover 300 may be configured to protect the display panel 200. For example, the panel cover 300 may include a light blocking layer, a heat dissipation layer, and a shielding layer.

The light blocking layer may block light incident on the display panel 200. For example, the light blocking layer may be disposed on the back surface of the display panel 200 to block light incident on the display panel 200 in the third direction DR3 and/or in a direction opposite to the third direction DR3. According to one embodiment, the light blocking layer may include a resin layer including polyethylene terephthalate (“PET”) or the like, and a light blocking layer positioned on a back surface of the resin layer. The light blocking layer may be a black tape or a coating layer made of a light blocking material.

The heat dissipation layer may be positioned on a back surface of the light blocking layer. For example, the heat dissipation layer may be disposed between the light blocking layer and the shielding layer. The heat dissipation layer may include a material with high thermal conductivity. Accordingly, heat generated in the display panel 200 can be effectively dissipated. For example, the heat dissipation layer may absorb heat generated in the display panel 200 and emit the absorbed heat through high thermal conductivity. According to one embodiment, the heat dissipation layer may include graphite. The graphite may have a plate-shaped structure in which carbon atoms are connected in a horizontal direction.

The shielding layer may be disposed on a back surface of the heat dissipation layer. For example, the shielding layer may be a bottom layer of the panel cover 300. In other words, the shielding layer may be a layer in contact with the back surface BS_PCB of the printed circuit board PCB. However, the present invention is not limited thereto. The shielding layer may be disposed on the back surface BS_PCB of the printed circuit board PCB to reduce the intensity of electromagnetic waves formed in the printed circuit board PCB in another embodiment.

According to one embodiment, the shielding layer may include at least one of various metal materials including aluminum (Al), copper (Cu), silver (Ag), magnesium (Mg), platinum (Pt), palladium (Pd), gold (Au), nickel (Ni), neodymium (Nd), iridium (Ir), chromium (Cr), titanium (Ti), molybdenum (Mo), or an alloy thereof, or may be formed as a multilayer or single layer including the above materials. In addition, the shielding layer may include at least one of conductive oxides such as indium tin oxide (“ITO”), indium zinc oxide (“IZO”), zinc oxide (ZnOx), or indium gallium zinc oxide (“IGZO”). The zinc oxide (ZnOx) may be zinc oxide (ZnO) and/or zinc peroxide (ZnO₂).

The bracket 400 may support the display panel 200 and the panel cover 300. One side of the bracket 400 may be attached to the panel cover 300, and the other side of the bracket 400 may be provided with a space where electronic components can be mounted.

The rear case 500 may accommodate the display panel 200 and the panel cover 300 and may be combined with the window member 100. The rear case 500 may include plastic or metal.

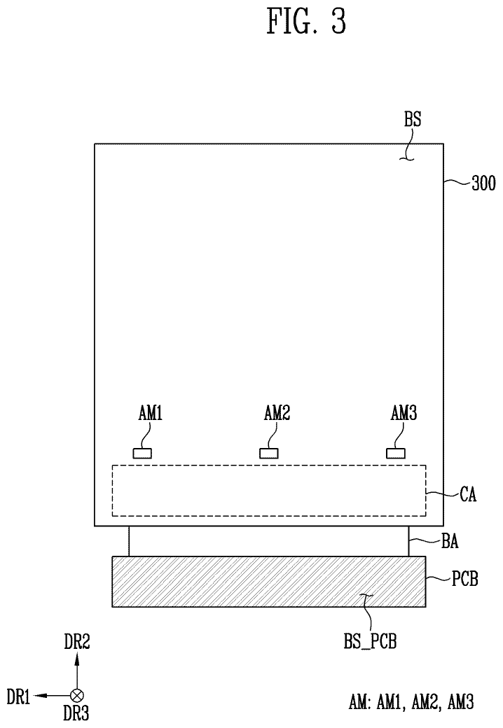

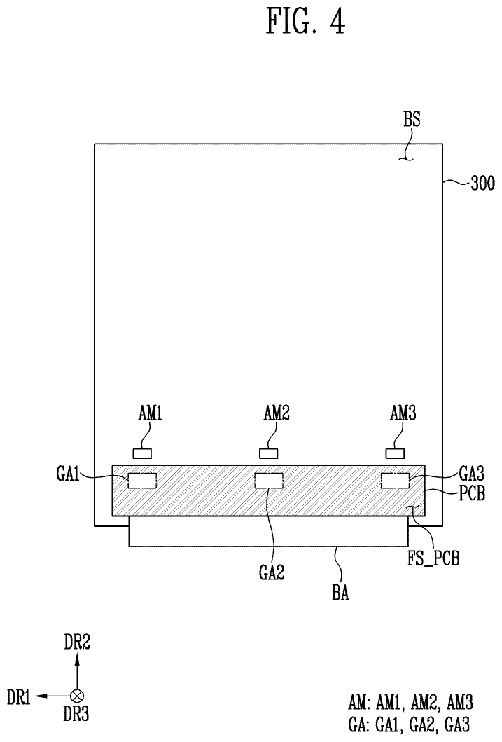

FIG. 3 is a plan view illustrating a panel cover and a printed circuit board before a bending area of FIG. 2 is bent. FIG. 4 is a plan view illustrating the panel cover and the printed circuit board after the bending area of FIG. 2 is bent. As used herein, the “plan view” is a view in a thickness direction (i.e., third direction DR3) of the display panel 200 or the panel cover 300.

In FIG. 3, the back surface BS of the panel cover 300 and the back surface BS_PCB of the printed circuit board PCB before the bending area BA is bent are shown. In FIG. 4, the back surface BS of the panel cover 300 and the back surface BS_PCB of the printed circuit board PCB after the bending area BA is bent are shown.

Referring to FIG. 3, the panel cover 300 may include alignment marks AM and a contact area CA. For example, first to third alignment marks AM1 to AM3 and the contact area CA may be disposed on the back surface BS of the panel cover 300.

The alignment marks AM may be arranged in one direction. For example, the first to third alignment marks AM1 to AM3 may be arranged on the back surface BS of the panel cover 300 in the first direction DR1. In FIG. 3, three alignment marks AM are shown as being arranged on the panel cover 300, but the present invention is not limited thereto.

The alignment marks AM may be disposed adjacent to the contact area CA. For example, each of the first to third alignment marks AM1 to AM3 may be disposed around the contact area CA in the second direction DR2.

Referring to FIGS. 3 and 4, the contact area CA may be disposed on the back surface BS of the panel cover 300. The contact area CA may be an area where the printed circuit board PCB overlaps in a plan view. For example, as the bending area BA is bent in a direction opposite to the third direction DR3, the printed circuit board PCB may be positioned on the back surface BS of the panel cover 300. In this case, the back surface BS_PCB of the printed circuit board PCB may be in contact with at least a portion of the contact area CA.

The alignment marks AM may be disposed outside the contact area CA. For example, the first to third alignment marks AM1 to AM3 may be disposed outside the contact area CA and may not overlap the printed circuit board PCB in a plan view.

The alignment marks AM may have a rectangular shape, but the present invention is not limited thereto. For another example, a plurality of alignment marks AM may have a shape such as a circle, triangle, pentagon, or diamond. In addition, the first to third alignment marks AM1 to AM3 may have different shapes.

According to one embodiment, the alignment marks AM may be imprinted on the back surface BS of the panel cover 300. However, this is only an example, and the method is not limited as long as the alignment marks AM can be disposed on the back surface BS of the panel cover 300.

The shape and size of the contact area CA may correspond to the shape and size of the printed circuit board PCB. Accordingly, in FIG. 3, the contact area CA is shown as a rectangular shape, but the present invention is not limited thereto and may have a shape corresponding to the shape of the printed circuit board PCB.

A printed circuit board PCB may include a plurality of ground areas GA. For example, first to third ground areas GA1 to GA3 may be disposed on a front surface FS_PCB of the printed circuit board PCB. The first to third ground areas GA1 to GA3 may be arranged in the first direction DR1. However, the present invention is not limited thereto.

Referring to FIG. 4, the printed circuit board PCB may be aligned on the panel cover 300 based on the alignment marks AM. For example, the printed circuit board PCB may be positioned on the back surface BS of the panel cover 300 as the bending area BA is bent in a direction opposite to the third direction DR3. In this case, the printed circuit board PCB may be aligned so that the ground areas GA disposed on the front surface FS_PCB of the printed circuit board PCB and the alignment marks AM are adjacent to each other. In other words, after the bending area BA is bent, the alignment marks AM and the ground areas GA may be positioned adjacent to each other. For example, the first alignment mark AM1 may be positioned adjacent to the first ground area GA1 in a direction opposite to the second direction DR2. In addition, the second alignment mark AM2 may be positioned adjacent to the second ground area GA2 in a direction opposite to the second direction DR2. Furthermore, the third alignment mark AM3 may be positioned adjacent to the third ground area GA3 in a direction opposite to the second direction DR2. In other words, the printed circuit board PCB may be aligned based on whether the alignment marks AM and the corresponding ground areas GA are arranged parallel to each other in the same direction (for example, the second direction DR2). Accordingly, the printed circuit board PCB may be stably aligned on the panel cover 300 based on the alignment marks AM. In other words, the reliability of a manufacturing process of the display device 1000 (see FIG. 2) can be effectively improved.

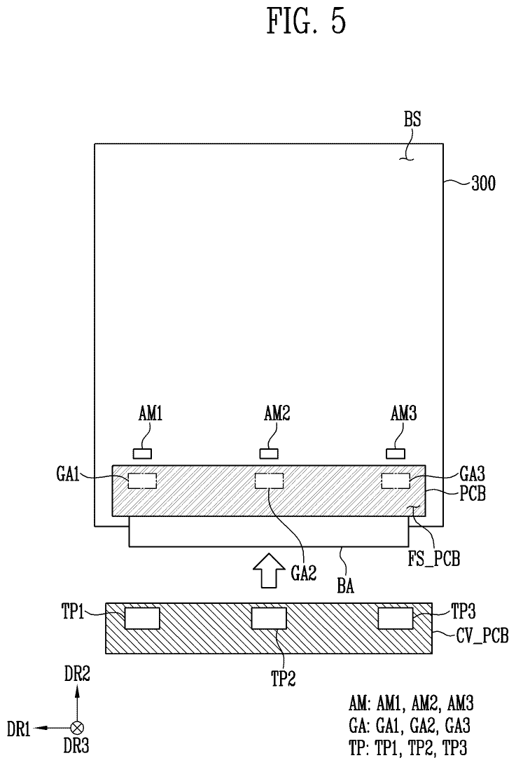

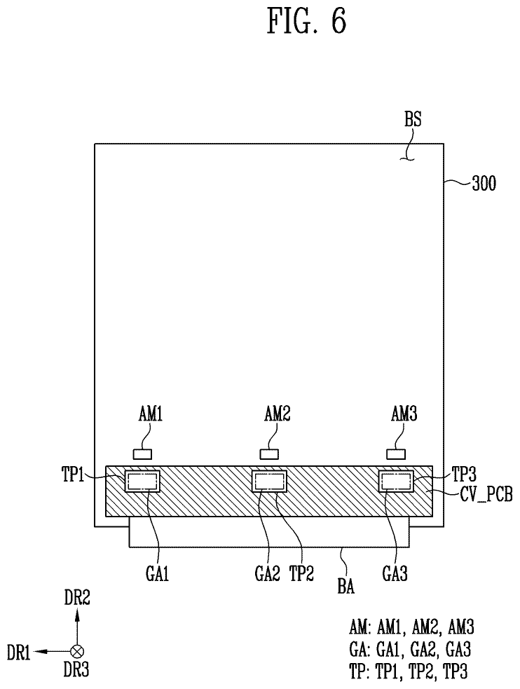

FIG. 5 is a plan view illustrating the panel cover, the printed circuit board, and a protective member according to an embodiment of the present invention. FIG. 6 is a plan view illustrating an embodiment in which the protective member of FIG. 5 is disposed on the panel cover.

Referring to FIG. 5, a protective member CV_PCB may include transparent portions TP. For example, the protective member CV_PCB may include first to third transparent portions TP1 to TP3 arranged in a direction opposite to the first direction DR1.

Referring to FIGS. 5 and 6, the protective member CV_PCB may be disposed on the printed circuit board PCB. For example, the protective member CV_PCB may contact at least a portion of the front surface FS_PCB of the printed circuit board PCB and overlap the printed circuit board PCB in a plan view.

When viewed on a plane (i.e., in a plan view), the protective member CV_PCB may have an area equal to or larger than an area of the printed circuit board PCB. For example, the protective member CV_PCB may have a relatively larger area than the printed circuit board PCB on a plane defined by the first direction DR1 and the second direction DR2 (i.e., in a plan view).

The protective member CV_PCB may cover at least a portion of the printed circuit board PCB. The protective member CV_PCB may be disposed to overlap the printed circuit board PCB in a plan view, and the protective member CV_PCB may not expose the front surface FS_PCB of the printed circuit board PCB to the outside. Accordingly, wirings and components disposed on the front surface FS_PCB of the printed circuit board PCB can be protected from the outside.

Each of the transparent portions TP may be disposed to overlap the ground areas GA in a plan view. For example, the first transparent portion TP1 may overlap the first ground area GA1. In addition, the second transparent portion TP2 may overlap the second ground area GA2. Furthermore, the third transparent portion TP3 may overlap the third ground area GA3 in a plan view.

The transparent portions TP may include a light transmissive material. For example, the transparent portions TP may be made of a transparent film. Accordingly, when viewed from the back surface BS of the panel cover 300 in the third direction DR3, the ground areas GA overlapping the transparent portions TP in a plan view may be visible from the outside. For example, the first ground area GA1 overlapping the first transparent portion TP1 may be visible when viewed from the third direction DR3 (i.e., in a plan view). In addition, the second ground area GA2 overlapping the second transparent portion TP2 may be visible when viewed from the third direction DR3. Furthermore, the third ground area GA3 overlapping the third transparent portion TP3 may be visible when viewed from the third direction DR3.

The protective member CV_PCB may be disposed on the printed circuit board PCB with improved reliability. For example, components to which electrical signals are applied may be disposed in areas adjacent to the ground areas GA of the printed circuit board PCB. The ground areas GA may be areas having a ground potential. In addition, the protective member CV_PCB may include areas (for example, the transparent portions TP) corresponding to the ground areas GA. In this case, if the protective member CV_PCB is not successfully aligned on the printed circuit board PCB, the ground areas GA may not have a ground potential. In other words, the protective member CV_PCB may include at least some conductive areas. In this case, when the ground areas GA overlap the conductive areas other than the transparent portions TP in a plan view, a short circuit may occur in the corresponding area. Accordingly, the ground areas GA may not have a ground potential, and the driving reliability of the display device 1000 (see FIG. 2) may deteriorate. For example, there may be a risk of electrostatic discharge (“ESD”) occurring as electromagnetic waves generated by the printed circuit board PCB are not reliably shielded.

According to one embodiment of the present invention, the protective member CV_PCB may be stably disposed so that the ground areas GA and the transparent portions TP completely overlap each other in a plan view. For example, when the protective member CV_PCB is disposed on the printed circuit board PCB, areas on the front surface FS_PCB of the printed circuit board PCB that overlap the transparent portions TP in a plan view may be visible from the outside. Accordingly, the protective member CV_PCB may be disposed on the printed circuit board PCB so that the transparent portions TP overlap the ground areas GA in a plan view, and the ground areas GA may have a ground potential. As the ground areas GA of the printed circuit board PCB have a stable ground potential, the driving reliability of the display device 1000 can be effectively improved.

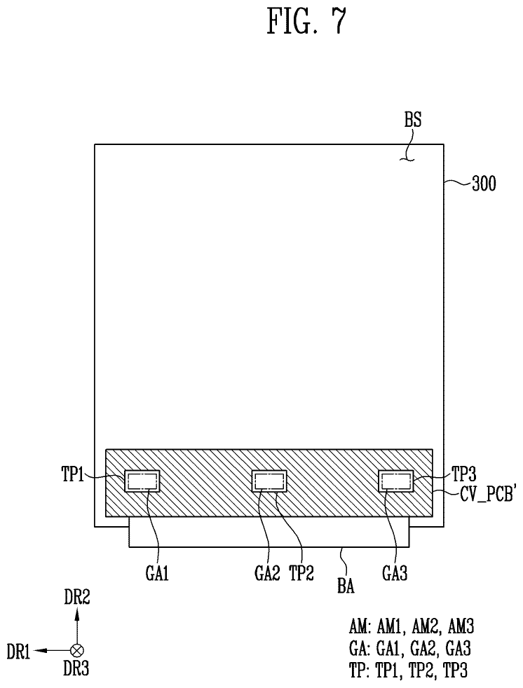

FIG. 7 is a plan view illustrating another embodiment in which the protective member of FIG. 5 is disposed on the panel cover.

Referring to FIG. 7, a protective member CV_PCB′ may be disposed on a printed circuit board PCB (see FIG. 5). For example, the protective member CV_PCB′ may be disposed on the printed circuit board PCB so as to overlap a front surface FS_PCB (see FIG. 5) of the printed circuit board PCB in a plan view.

A panel cover 300, a bending area BA, ground areas GA, and transparent portions TP of FIG. 7 may be described similarly to the panel cover 300, the bending area BA, the ground areas GA, and the transparent portions TP of FIG. 6. Hereinafter, overlapping descriptions will be omitted.

According to one embodiment, the protective member CV_PCB′ may cover alignment marks AM (see FIG. 6). For example, when viewed on a plane (i.e., in a plan view), the protective member CV_PCB′ of FIG. 7 may have a relatively larger area than the protective member CV_PCB of FIG. 6. Accordingly, the protective member CV_PCB′ may cover at least one of the alignment marks AM. However, the present invention is not limited thereto. For another example, the protective member CV_PCB′ may cover only a first alignment mark AM1, which is one of the alignment marks AM, and may not cover a second alignment mark AM2 and a third alignment mark AM3.

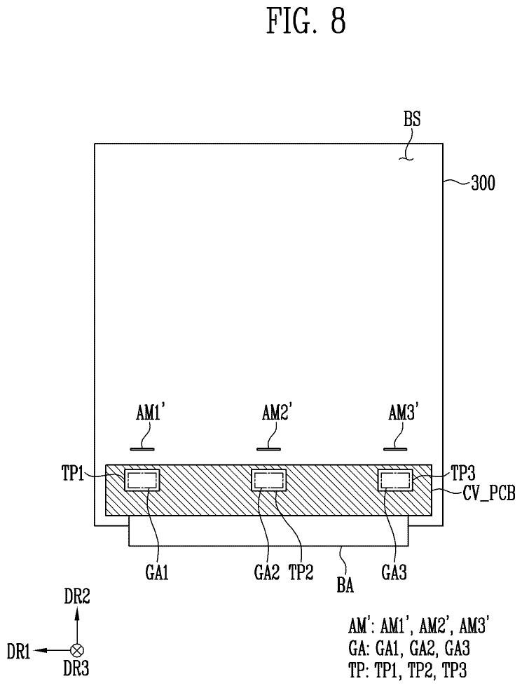

FIG. 8 is a plan view illustrating an embodiment of alignment marks in a state in which the protective member of FIG. 5 is disposed on the panel cover.

Referring to FIG. 8, a panel cover 300 may include alignment marks AM′. For example, first to third alignment marks AM1′ to AM3′ may be arranged on a back surface BS of the panel cover 300 in the first direction DR1.

The panel cover 300, a bending area BA, ground areas GA, and transparent portions TP of FIG. 8 may be described similarly to the panel cover 300, the bending area BA, the ground areas GA, and the transparent portions TP of FIG. 6. Hereinafter, overlapping descriptions will be omitted.

The alignment marks AM′ may have a line shape. For example, at least one of the first to third alignment marks AM1′ to AM3′ may have a line shape. However, the present invention is not limited thereto. For another example, the first alignment mark AM1′ may have a line shape, and the second alignment mark AM2′ and the third alignment mark AM3′ may have a rectangular shape as shown in FIG. 6.

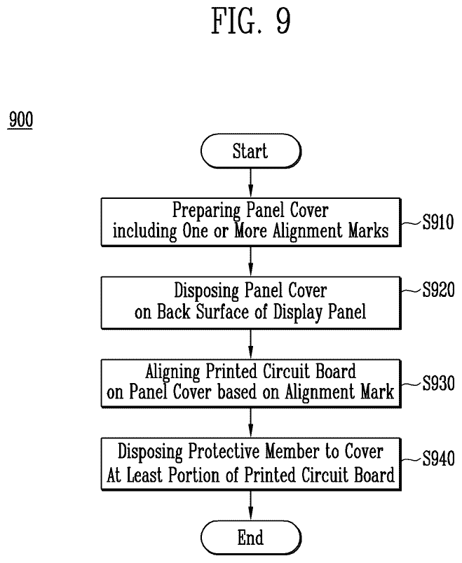

FIG. 9 is a flowchart illustrating a manufacturing method of a display device according to an embodiment of the present invention.

Referring to FIG. 9, a manufacturing method 900 of a display device according to an embodiment of the present invention may include preparing a panel cover including one or more alignment marks (S910), disposing the panel cover on a back surface of a display panel (S920), aligning a printed circuit board on the panel cover based on the alignment mark (S930), and disposing a protective member to cover at least a portion of the printed circuit board (S940).

Referring to FIGS. 2, 3, and 9, in the preparing of the panel cover including one or more alignment marks (S910), a panel cover 300 including alignment marks AM may be prepared. For example, the alignment marks AM may be formed on a back surface BS of the panel cover 300. In other words, first to third alignment marks AM1 to AM3 may be arranged on the back surface BS of the panel cover 300 in the first direction DR1. According to one embodiment, the alignment marks AM may be imprinted on the back surface BS of the panel cover 300.

Referring to FIGS. 2, 3, and 9, in the disposing the panel cover on the back surface of the display panel (S920), the panel cover 300 may be disposed on a back surface of a display panel 200. For example, the panel cover 300 may be disposed so that the back surface of the display panel 200 faces a front surface FS of the panel cover 300.

Referring to FIGS. 3, 4, and 9, the aligning of the printed circuit board on the panel cover based on the alignment mark (S930) may include bending a bending area BA so that a printed circuit board PCB is positioned on the back surface BS of the panel cover 300. For example, the bending area BA may be bent in a direction opposite to the third direction DR3, and a back surface BS_PCB of the printed circuit board PCB may be in contact with a contact area CA.

When the printed circuit board PCB is aligned, ground areas GA may be disposed around the alignment marks AM. For example, each of first to third ground areas GA1 to GA3 may be arranged adjacent to the first to third alignment marks AM1 to AM3 in the second direction DR2, respectively. In other words, in the aligning the printed circuit board on the panel cover based on the alignment mark (S930), the printed circuit board PCB may be aligned so that the first to third ground areas GA1 to GA3 are arranged parallel to the first to third alignment marks AM1 to AM3 in the second direction DR2, respectively.

Referring to FIGS. 5, 6, and 9, in the disposing of the protective member to cover at least a portion of the printed circuit board (S940), a protective member CV_PCB may be disposed on a front surface FS_PCB of the printed circuit board PCB. Accordingly, the protective member CV_PCB may cover the printed circuit board PCB. According to one embodiment, the protective member CV_PCB may completely cover the printed circuit board PCB. Referring to FIG. 7 together, the protective member CV_PCB may also cover the alignment marks AM. However, the present invention is not limited thereto.

In the disposing the protective member to cover at least a portion of the printed circuit board (S940), the protective member CV_PCB may be disposed on the printed circuit board PCB so that transparent portions TP overlap the ground areas GA in a plan view. Accordingly, the ground areas GA may be visible from the outside, and the protective member CV_PCB may be disposed in an intended area on the printed circuit board PCB.

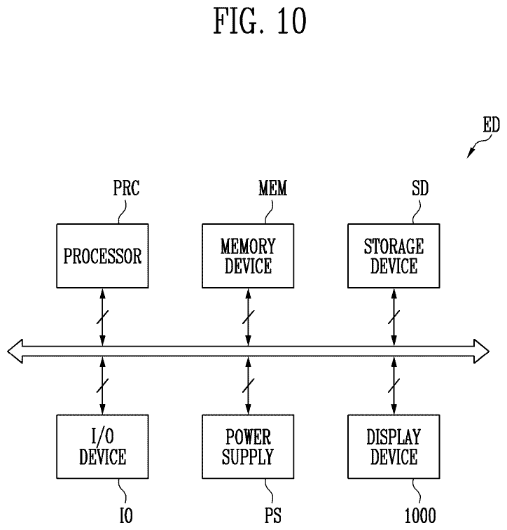

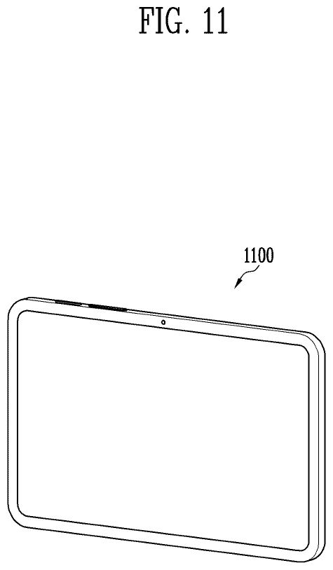

FIG. 10 is a block diagram illustrating an electronic device including a display device according to embodiments of the present invention. FIG. 11 is a perspective view illustrating an example in which the electronic device of FIG. 10 is implemented as a tablet PC (personal computer).

Referring to FIGS. 10 and 11, an electronic device ED may include a processor PRC, a memory device MEM, a storage device SD, an input/output device IO, a power supply PS, and a display device 1000. In this case, the display device 1000 may be the display device 1000 of FIG. 1. In addition, the electronic device ED may further include several ports capable of communicating with a video card, a sound card, a memory card, a universal serial bus (“USB”) device, or other systems. In one embodiment, as shown in FIG. 11, the electronic device ED may be implemented as a tablet PC. However, this is only an example, and the electronic device ED is not limited thereto. For another example, the electronic device ED may be implemented as a mobile phone, a video phone, a smart pad, a smart watch, a car navigation system, a computer monitor, a laptop, a head-mounted display device, or the like.

The processor PRC may perform specific calculations or tasks. According to one embodiment, the processor PRC may be a microprocessor, a central processing unit, an application processor, or the like. The processor PRC may be connected to other components through an address bus, a control bus, a data bus, and the like. According to one embodiment, the processor PRC may also be connected to an expansion bus such as a peripheral component interconnect (“PCI”) bus.

The memory device MEM may store data for the operation of the electronic device ED. For example, the memory device MEM may include a non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“ARAM”) device, a nano floating gate memory (“NFGM”) device, a polymer random access memory (“PoRAM”) device, a magnetic random access memory (“MRAM”) device, and a ferroelectric random access memory (“FRAM”) device and/or a volatile memory device such as a dynamic random access memory (“DRAM”) device, a static random access memory (“SRAM”) device, and a mobile DRAM device.

The storage device SD may include a solid state drive (“SSD”), a hard disk drive (“HDD”), a compact disc read only memory (“CD-ROM”), and the like.

The input/output device IO may include an input means such as a keyboard, a keypad, a touchpad, a touch screen, and a mouse and an output means such as a speaker and a printer. According to one embodiment, the display device 1000 may be included in the input/output device IO.

The power supply PS may supply power sources for the operation of the electronic device ED. For example, the power supply PS may be a power management integrated circuit (“PMIC”).

The display device 1000 may display an image corresponding to visual information of the electronic device ED. In this case, the display device 1000 may be an organic light emitting display device or a quantum dot light emitting display device, but the present invention is not limited thereto. The display device 1000 may be connected to other components through buses or other communication links in another embodiment.

Referring to FIG. 11, the reliability of a tablet PC 1100 including the display device according to embodiments of the present disclosure can be improved during a manufacturing process and while driving.

According to the embodiments of the present invention, a display device with improved reliability of a manufacturing process by aligning a printed circuit board on a panel cover based on alignment marks, a manufacturing method thereof, and an electronic device including the same can be provided.

In addition, according to the embodiments of the present invention, a display device with improved driving reliability by disposing a protective member on a printed circuit board based on transparent portions, a manufacturing method thereof, and an electronic device including the same can be provided.

Effects according to the embodiments of the present invention are not limited to those described above, and various other effects are included in the present specification.

Although specific embodiments and applications have been described herein, other embodiments and variations may be derived from the above description. Accordingly, the spirit of the invention is not limited to these embodiments, but extends to the scope of the claims set forth below, various obvious modifications, and equivalents.

What is claimed is:

1. A display device comprising:
a display panel;
a panel cover disposed on a back surface of the display panel and including one or more alignment marks located on a back surface of the panel cover;
a printed circuit board disposed on the back surface of the panel cover and including a ground area located around the one or more alignment marks; and
a protective member disposed on the printed circuit board and including a transparent portion at least partially overlapping the ground area in a plan view.

2. The display device of claim 1, wherein the protective member is disposed to cover at least a portion of the printed circuit board, and
wherein the transparent portion includes a light transmissive material.

3. The display device of claim 2, wherein the transparent portion has an area equal to or larger than the ground area in the plan view.

4. The display device of claim 3, wherein the protective member covers the one or more alignment marks.

5. The display device of claim 1, wherein the printed circuit board is disposed to overlap a contact area disposed on the back surface of the panel cover in the plan view, and
wherein the one or more alignment marks are disposed outside the contact area.

6. The display device of claim 5, wherein the one or more alignment marks are provided in plurality, and the plurality of alignment marks are disposed on the back surface of the panel cover,
wherein the ground area is provided in plurality, and the plurality of ground areas are disposed on the printed circuit board,
wherein the plurality of alignment marks are disposed adjacent to each other in a first direction,
wherein one of the plurality of ground areas is disposed adjacent to a corresponding one of the plurality of alignment marks in a second direction, and
wherein the first direction and the second direction intersect each other.

7. The display device of claim 6, wherein the display panel further includes a bending area disposed at an end of the display panel and connected to the printed circuit board, and
wherein as the bending area is bent in a third direction that intersects the first direction and the second direction, the printed circuit board is positioned on the back surface of the panel cover.

8. The display device of claim 1, wherein the ground area has a ground potential.

9. The display device of claim 1, wherein the one or more alignment marks have a line shape.

10. The display device of claim 9, wherein the one or more alignment marks are imprinted on the panel cover.

11. An electronic device comprising:
a display device configured to display an image based on input image data; and
a processor configured to provide the input image data to the display device,
wherein the display device includes:
a display panel;
a panel cover disposed on a back surface of the display panel and including one or more alignment marks;
a printed circuit board aligned on the panel cover based on the one or more alignment marks and including one or more ground areas; and
a protective member disposed on the printed circuit board and including one or more transparent portions overlapping the one or more ground areas in a plan view.

12. A manufacturing method of a display device comprising:
preparing a panel cover including one or more alignment marks;
disposing the panel cover on a back surface of a display panel;
aligning a printed circuit board including one or more ground areas on the panel cover based on the one or more alignment marks; and
disposing a protective member including one or more transparent portions to cover at least a portion of the printed circuit board.

13. The manufacturing method of claim 12, wherein the disposing of the protective member includes aligning at least a portion of the one or more transparent portions to overlap the one or more ground areas in a plan view.

14. The manufacturing method of claim 12, further comprising:
forming each of the one or more transparent portions to have an area equal to or larger than each of the one or more ground areas in a plan view.

15. The manufacturing method of claim 12, wherein the disposing of the protective member includes disposing the protective member to cover at least one of the one or more alignment marks.

16. The manufacturing method of claim 12, wherein the preparing of the panel cover includes disposing the one or more alignment marks to be arranged on a back surface of the panel cover in a first direction.

17. The manufacturing method of claim 16, wherein the aligning of the printed circuit board on the panel cover includes aligning the printed circuit board so that one of the one or more ground areas is disposed adjacent to a corresponding one of the one or more alignment marks in a second direction intersecting the first direction.

18. The manufacturing method of claim 17, wherein the aligning of the printed circuit board on the panel cover includes bending a bending area disposed at an end of the display panel and connected to the printed circuit board so that the printed circuit board is positioned on the back surface of the panel cover.

19. The manufacturing method of claim 12, wherein the one or more ground areas have a ground potential.

20. The manufacturing method of claim 12, wherein the one or more alignment marks have a line shape.
